(19) United States
(12) Patent Application Publication
(10) Pub. No.: US 2023/0028669 A1
(43) Pub. Date: Jan. 26, 2023

(54) PLASMA PROCESSING APPARATUS

(71) Applicant: CHANGXIN MEMORY TECHNOLOGIES, INC., Hefei City (CN)

(72) Inventor: Fencheng ZHENG, Hefei (CN)

(21) Appl. No.: 17/498,798

(22) Filed: Oct. 12, 2021

Related U.S. Application Data
(63) Continuation of application No. PCT/CN2021/109702, filed on Jul. 30, 2021.

(30) Foreign Application Priority Data
Jul. 16, 2021 (CN) 202110807355.1

(51) Int. Cl. H01J 37/32

(52) U.S. Cl. CPC H01J 37/32724; H01J 37/32642; H01J 2237/2007; H01J 2237/002; H01J 2237/334

(57) ABSTRACT

A plasma processing apparatus includes an electrostatic chuck, a connection surface being provided at a periphery of the electrostatic chuck; an edge adjustment ring, arranged around the electrostatic chuck in a circumferential direction, an inner wall of the edge adjustment ring being opposite to an outer wall of the electrostatic chuck; and an edge ring, arranged around the electrostatic chuck and above the connection surface, and located above the edge adjustment ring. The edge adjustment ring includes an annular body and an annular protrusion protruding toward the edge ring, and the annular body is relatively close to the electrostatic chuck.

### CROSS-REFERENCE TO RELATED APPLICATIONS

This application is a continuation application of International Application No. PCT/CN2021/109702, filed on Jul. 30, 2021, which claims priority to Chinese Patent Application No. 202110807355.1, filed on Jul. 16, 2021. The disclosures of International Application No. PCT/CN2021/109702 and Chinese Patent Application No. 202110807355.1 are hereby incorporated by reference in their entireties.

### BACKGROUND

In the related art, a plasma processing apparatus is usually used to perform a process such as deposition or etching on a workpiece.

However, in the related art, when a plasma processing apparatus performs plasma processing, plasma will etch some structures in the apparatus. In addition, due to relatively high requirements for mounting positions and heights of some structures in the plasma processing apparatus, the mounting of the apparatus is difficult. Therefore, it is an urgent problem to provide a plasma processing apparatus which is simple to mount and good in airtightness.

### SUMMARY

The embodiments of this disclosure relate to, but are not limited to, a plasma processing apparatus.

The embodiments of this disclosure provide a plasma processing apparatus, including an electrostatic chuck, an edge adjustment ring and an edge ring.

The electrostatic chuck has a connection surface at its periphery.

The edge adjustment ring is arranged around the electrostatic chuck in a circumferential direction, and an inner wall of the edge adjustment ring is opposite to an outer wall of the electrostatic chuck.

The edge ring is arranged around the electrostatic chuck and above the connection surface, and is located above the edge adjustment ring.

The edge adjustment ring includes an annular body and an annular protrusion protruding toward the edge ring, in which the annular body is relatively close to the electrostatic chuck.

### BRIEF DESCRIPTION OF THE DRAWINGS

FIG. 1A and FIG. 1B are partial schematic structural diagrams of a plasma processing apparatus in the related art.

FIG. 2 is an optional partial schematic structural diagram of a plasma processing apparatus provided by embodiments of this disclosure.

FIG. 3A to FIG. 3H are partial schematic structural diagrams of a plasma processing apparatus provided by embodiments of this disclosure.

### DETAILED DESCRIPTION

The specific technical solutions of this disclosure will be further described in detail below with reference to the accompanying drawings in the embodiments of this disclosure. The following embodiments are intended to illustrate this disclosure, but are not intended to limit the scope of this disclosure.

In the following description, a number of specific details are given in order to provide a more thorough understanding of this disclosure. However, it is apparent to those skilled in the art that this disclosure can be implemented without one or more of these details. In other examples, in order to avoid confusion with this disclosure, some technical features known in the art are not described. That is, not all the features of actual embodiments are described. Well-known functions and structures are not described in detail here.

In the accompanying drawings, the sizes of layers, regions, and elements and their relative sizes may be exaggerated for clarity. Same reference numbers are used to represent same elements throughout the drawings.

It should be understood that, when an element or layer is referred to as being “on”, “adjacent to”, “connected to” or “coupled to” another element or layer, it can be disposed directly on the another element or layer, adjacent to, connected or coupled to the another element or layer, or an intervening element or layer may also be present therebetween. In contrast, when an element is referred to as being “directly on”, “directly adjacent to”, “directly connected to” or “directly coupled to” another element or layer, there is no intervening element or layer present therebetween. It should be understood that, although the terms “first”, “second”, “third”, etc. may be used herein to describe various elements, components, regions, layers, and/or portions, these elements, components, regions, layers and/or portions should not be limited by these terms. These terms are only used to distinguish one element, component, region, layer or portion from another element, component, region, layer or portion. Thus, a first element, component, region, layer or portion discussed below could be termed a second element, component, region, layer or portion, without departing from the teachings of this disclosure. Moreover, when a second element, component, region, layer or portion is discussed, it does not mean that a first element, component, region, layer or portion is necessarily present in this disclosure.

Spatial relationship terms, such as “under”, “below”, “lower”, “underneath”, “above”, and “upper”, are used herein for convenience to describe a relationship of one element or feature with another element or feature as illustrated in the drawings. It should be understood that, in addition to the orientation depicted in the drawings, these spatial relationship terms are intended to encompass different orientations of devices in use and during operation. For example, if a device shown in the drawings is flipped, an element or feature described as “under” or “below” or “underneath” another element would then be oriented as “above” the another element or feature. Therefore, the exemplary terms “below” and “under” can encompass both orientations of “above” and “below”. Devices can be positioned in other different orientations (e.g., rotated 90 degrees or in other orientations), and the spatial relationship terms used herein should be interpreted accordingly.

The terms used herein are only for the purpose of describing the specific embodiments and are not intended to limit this disclosure. Unless clearly indicated otherwise in the context, as used herein, the singular terms “a”, “an” and “the” are also intended to include plural forms. It should be further understood that the terms “consist of” and/or “include”, when used in this description, specify the presence of stated features, integers, steps, operations, elements and/or components, but do not preclude the presence or addition of one or more other features, integers, steps, operations, elements, components and/or groups thereof. As used herein, the term “and/or” includes any and all combinations of related listed items.

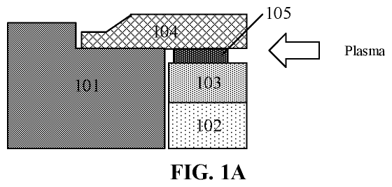

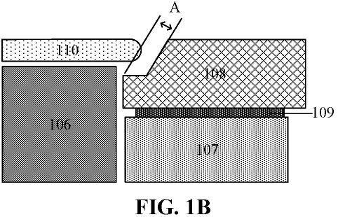

FIG. 1A and FIG. 1B are partial schematic structural diagrams of a plasma processing apparatus in the related art. As shown in FIG. 1A, in the related art, a plasma processing apparatus includes an electrostatic chuck 101, and a base 102, an edge adjustment ring 103 and an edge ring 104 provided around the electrostatic chuck. The edge adjustment ring 103 and the edge ring 104 are connected by a thermally conductive adhesive 105.

The plasma processing apparatus in the related art is provided with a processing chamber, the plasma processing apparatus is located in the processing chamber, and the plasma processing apparatus allows a workpiece to be fixed on the electrostatic chuck by electrostatic adsorption. When the workpiece is etched by plasma, the thermally conductive adhesive 105 will also be etched, which will cause undesired particles to be generated when the thermally conductive adhesive is etched. These undesired particles may contaminate the workpiece and reduce the yield of the workpiece. Moreover, because the thermally conductive adhesive is etched by the plasma, the thermal conductivity of the thermally conductive adhesive is reduced, resulting in low thermal conductivity of the plasma processing apparatus in the related art.

A partial schematic structural diagram of a plasma processing apparatus in the related art is shown in FIG. 1B. The plasma processing apparatus includes an electrostatic chuck 106, and an edge adjustment ring 107 and an edge ring 108 provided around the electrostatic chuck. The edge adjustment ring 107 and the edge ring 108 are connected by a thermally conductive adhesive 109.

The thermally conductive adhesive has adhesion. The thermally conductive adhesive 109 between the edge adjustment ring 107 and the edge ring 108 is pressed for adhesion to connect the edge adjustment ring and the edge ring. In the process of pressing the thermally conductive adhesive for adhesion, many bubbles will be generated between the thermally conductive adhesive 109 and the edge adjustment ring 107. Because these bubbles will expand or break after the pressure changes, damage is caused to the adhesion of the thermally conductive adhesive. Moreover, the expansion or break of the bubbles will change the height of the thermally conductive adhesive, causing changes to the height of the edge ring, and damaging the structure of the plasma apparatus. Therefore, in the related art, repeated air extraction is needed to remove bubbles, but this not only damage the adhesion of the thermally conductive adhesive, but also affect the thermal conductivity of the thermally conductive adhesive.

Referring to FIG. 1B again, a workpiece 110 is fixed on the electrostatic chuck 106 by electrostatic adsorption above the electrostatic chuck. Here, the workpiece refers to a structure to be processed that can be processed by the plasma processing apparatus using plasma, such as a wafer.

In the process that the plasma processing apparatus in the related art performs task processing, a certain potential difference is generated between an edge of the workpiece 110 and the edge ring 108. When the distance A between the workpiece 110 and the edge ring 108 is too small, capacitor arcing may occur, causing a defect on the edge of the workpiece 110.

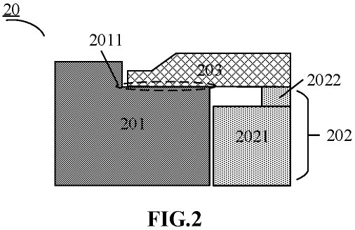

In view of the problem in the related art, the embodiments of this disclosure provide a plasma processing apparatus. FIG. 2 is an optional partial schematic structural diagram of a plasma processing apparatus provided by the embodiments of this disclosure.

As shown in FIG. 2, an plasma processing apparatus 20 includes: an electrostatic chuck 201, a connection surface 2011 (shown in the dashed box in the figure) being provided at a periphery of the electrostatic chuck; an edge adjustment ring 202, provided in a circumferential direction of the electrostatic chuck 201, an inner wall of the edge adjustment ring 202 being opposite to an outer wall of the electrostatic chuck 201; and an edge ring 203, provided around the electrostatic chuck 201 and above the connection surface 2011, and located above the edge adjustment ring 202. The edge adjustment ring 202 includes an annular body 2021 and an annular protrusion 2022 protruding toward the edge ring 203, in which the annular body 2021 is relatively close to the electrostatic chuck 201.

In some embodiments, the plasma processing apparatus allows a wafer to be fixed on the electrostatic chuck by electrostatic adsorption, and performs etching or deposition processing on a workpiece such as the wafer.

In some embodiments, the edge adjustment ring 202 may be made of ceramic, so that the edge adjustment ring has good heat insulation performance. The edge ring 203 may be made of silicon, silicon nitride, or silicon dioxide.

According to the plasma processing apparatus provided by the embodiments of this disclosure, the edge ring is fixed through the edge adjustment ring and the electrostatic chuck, and thus, the structure is simple and mounting is facilitated. Moreover, the edge adjustment ring is connected to the edge ring through the annular protrusion, and thus, the probability of plasma entering the space between the edge adjustment ring and the edge ring is reduced, thereby alleviating the problem that particles are generated due to plasma etching internal structures of the plasma processing apparatus.

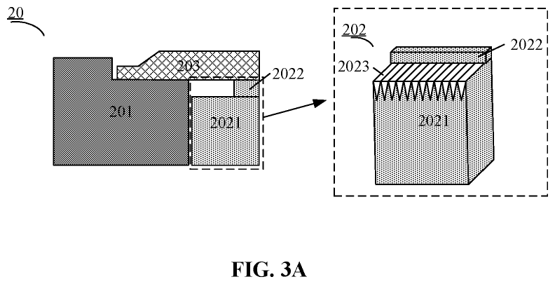

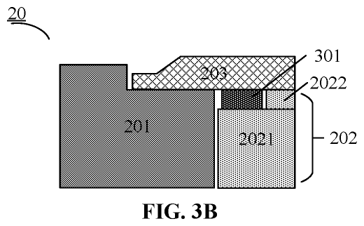

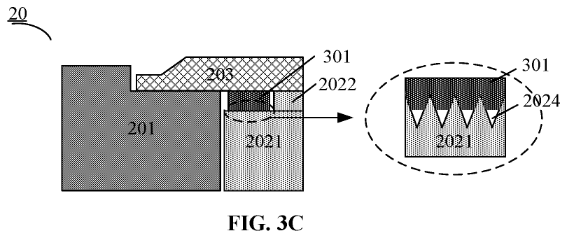

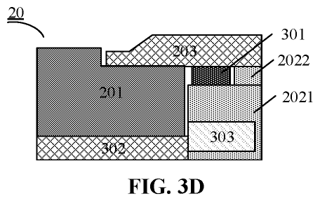

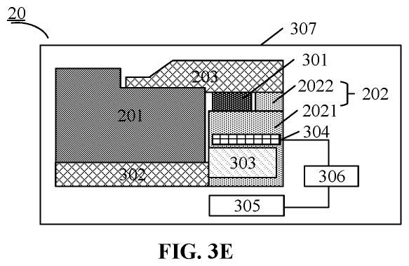

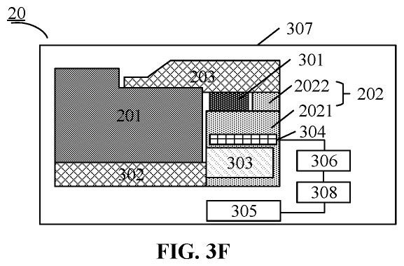

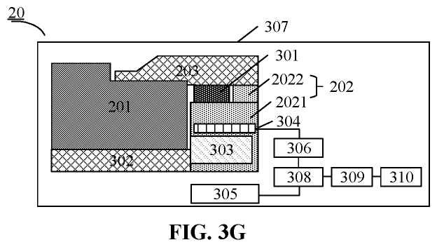

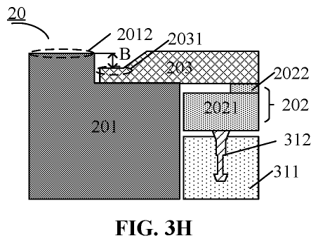

FIG. 3A to FIG. 3H are partial schematic structural diagrams of a plasma processing apparatus provided by embodiments of this disclosure. The structure in the dashed box in the right drawing in FIG. 3A is a partially enlarged schematic view of the edge adjustment ring 202. Referring to FIG. 3A, the edge adjustment ring 202 further includes grooves 2023 recessed in a direction away from the edge ring 203. The grooves 2023 are located at a surface of the annular body 2021 relatively close to the edge ring 203 and between the annular protrusion 2022 and the electrostatic chuck 201.

In some embodiments, all the grooves 2023 may be disposed at equal intervals on the annular body 2021, or a fixed number of grooves may be continuously disposed in a circumferential direction of the annular body 2021 at an equal interval. The embodiments of this disclosure do not limit the distribution mode of the grooves.

In some embodiments, the depth and width of the grooves may be less than one millimeter.

FIG. 3B is a partial schematic structural diagram of a plasma processing apparatus provided by the embodiments of this disclosure.

In some embodiments, as shown in FIG. 3B, the plasma processing apparatus 20 further includes a first thermally conductive structure 301, located between the annular body 2021 and the edge ring 203, configured to bond the edge adjustment ring 202 and the edge ring 203, and further configured to transfer heat between the annular body 2021 and the edge ring 203.

In some embodiments, the first thermally conductive structure may be a thermally conductive adhesive, which has adhesion. Therefore, the first thermally conductive structure can connect to the edge adjustment ring and the edge ring through its own adhesion.

In some embodiments, the annular protrusion and the electrostatic chuck enables the first thermally conductive structure to be fixed between the annular protrusion and the electrostatic chuck, thereby alleviating the problem that the thermal conductivity of the plasma processing apparatus is affected by a change in the position of the first thermally conductive structure.

In the plasma processing apparatus provided by the embodiments of this disclosure, the first thermally conductive structure is located between the annular protrusion and the electrostatic chuck, and the annular protrusion limits the position of the edge ring, so that the first thermally conductive structure will not be compacted to affect the thermal conductivity of the first thermally conductive structure. Moreover, when the plasma processing apparatus performs etching by plasma, the plasma cannot etch the first thermally conductive structure by passing through a space between the edge adjustment ring and the edge ring, thereby avoiding the problems of contamination of the workpiece caused by particles generated if the first thermally conductive structure is etched and the influence to the thermal conductivity of the first thermally conductive structure, improving the thermal conductivity of the plasma processing apparatus, and improving the product yield.

FIG. 3C is a partially enlarged schematic view of a joint between the edge adjustment ring and the first thermally conductive structure provided by the embodiments of this disclosure. As shown in FIG. 3C, a partially enlarged schematic view of a joint between the annular body 2021 of the edge adjustment ring and the first thermally conductive structure 301 is shown in the dashed box in the right drawing.

In some embodiments, the first thermally conductive structure 301 partially fills in the grooves, such that there are gaps 2024 between the bottom of the first thermally conductive structure 301 and bottoms of the grooves. The volume of a gap 2024 is smaller than that of a groove, and there is no filler in the gap 2024.

In some embodiments, the first thermally conductive structure will fill parts of the grooves of the edge adjustment ring after connected to the edge adjustment ring. Compared with the planar structure of an edge adjustment ring in the related art, after the first thermally conductive structure in the embodiments of this disclosure fills parts of the grooves, the contact area between the first thermally conductive structure and the edge adjustment ring is increased, and the increase in the contact area between the first thermally conductive structure and the edge adjustment ring improves the thermal conductivity.

In some embodiments, the plasma processing apparatus provided by the embodiments of this disclosure has a processing chamber, and the plasma processing apparatus performs the plasma processing task in the processing chamber.

It should be noted that, due to the edge adjustment ring having a groove structure provided in the embodiments of this disclosure, after the first thermally conductive structure and the edge adjustment ring are connected, there are gaps between the bottom of the first thermally conductive structure and the bottoms of the grooves, thereby reducing the probability of bubbles generated when the first thermally conductive structure is connected to the edge adjustment ring, and alleviating the problems of the damage to the adhesion of the first thermally conductive structure and the influence on the thermal conduction between the first thermally conductive structure and the edge ring caused by expansion of the bubbles when the temperature and pressure change.

In the plasma processing apparatus provided in the embodiments of this disclosure, due to the edge adjustment ring having a groove structure at the surface, after the edge adjustment ring and the first thermally conductive structure are connected, there are gaps in the grooves of the edge adjustment ring, in which the gaps are communicated with the interior of the processing chamber of the plasma processing apparatus. The pore structure reduces the probability of bubbles generated between the edge adjustment ring and the first thermally conductive structure, thereby alleviating the damage to the adhesion of the thermally conductive adhesive caused by the expansion or break of the bubbles when the pressure changes, and alleviating the problem of the damage to the structure of the plasma apparatus due to change in the height of the edge ring caused by change in the height of the thermally conductive adhesive due to the expansion or break of the bubbles. Moreover, the structure provided in the embodiments of this disclosure omits the step of removing bubbles through air extraction, thereby reducing labor cost and time cost.

FIG. 3D is a partial schematic structural diagram of a plasma processing apparatus provided by the embodiments of this disclosure. As shown in FIG. 3D, the plasma processing apparatus 20 further includes a cooling assembly 302 located below the electrostatic chuck 201 and configured to cool the electrostatic chuck 201, and a second thermally conductive structure 303 located in the annular body 2021. The second thermally conductive structure 303 contacts the cooling assembly 302, and the second thermally conductive structure 303 is configured to conduct heat to the cooling assembly 302.

In some embodiments, according to the plasma processing apparatus provided by the embodiments of this disclosure, heat generated during etching by plasma is transferred to the bottom of the plasma processing apparatus. That is, the heat is transferred to the electrostatic chuck, and the cooling assembly is located below the electrostatic chuck to lower the temperature of the plasma processing apparatus.

In some embodiments, the plasma processing apparatus 20 further includes a plurality of second thermally conductive structures (the plurality of second thermally conductive structures are shown in the figures). The plurality of second thermally conductive structures 303 are located in the annular body 2021 and disposed at equal intervals in the circumferential direction of the annular body 2021.

In some embodiments, a second thermally conductive structure may be a PN junction consisting of a P-type semiconductor and an N-type semiconductor. When the plasma processing apparatus works, the second thermally conductive structure will actively absorb or release heat depending on the temperature of the plasma apparatus to adjust the temperature of the edge adjustment ring, and transfer the heat to the cooling assembly 302, thereby improving the heat transfer efficiency of the plasma processing apparatus. Moreover, by adjusting the temperature of the edge adjustment ring by the second thermally conductive structure, the edge temperature of the workpiece when the plasma processing apparatus works is adjusted, so that when the plasma processing apparatus performs a task, the difference of the temperatures of the workpiece surface and the workpiece edge is not great, thus the workpiece surface can be more uniformly etched or deposited, thereby improving the product yield of the workpiece.

According to the plasma processing apparatus provided by the embodiments of this disclosure, second thermally conductive structures are uniformly provided in the edge adjustment ring, so that the temperature of the edge adjustment ring can be adjusted by the second thermally conductive structures, thereby adjusting the edge etching rate of a workpiece during etching, and avoiding the problems of uneven etching and etching defects at the workpiece edge caused by temperature. Moreover, the heat transfer efficiency of the plasma processing apparatus is improved by providing a cooling assembly.

FIG. 3E is a partial schematic structural diagram of a plasma processing apparatus provided by the embodiments of this disclosure.

In some embodiments, as shown in FIG. 3E, the plasma processing apparatus 20 further includes a first temperature sensing unit 304, located in the edge adjustment ring 202, and configured to measure the temperature of the edge adjustment ring 202 to obtain a first measurement result.

In some embodiments, the plasma processing apparatus 20 further includes a second temperature sensing unit 305, located in a cavity 307 (the solid line box in FIG. 3E) of the plasma processing apparatus. The second temperature sensing unit 305 is configured to measure the temperature in the plasma processing apparatus 20 to obtain a second measurement result. The cavity 307 is configured to accommodate structures such as the electrostatic chuck 201, the edge adjustment ring 202, the edge ring 203, and the second temperature sensing unit 305.

It should be noted that the plasma processing apparatus 20 is provided with a processing chamber, in which the plasma processing apparatus is located inside the cavity of the processing chamber.

Here, the first temperature sensing unit 304 and the second temperature sensing unit 305 may be any temperature sensor such as a laser temperature sensor. The first temperature sensing unit and the second temperature sensing unit are configured for temperature measurement. The actual types of the first temperature sensing unit and the second temperature sensing unit are not limited in this disclosure.

In some embodiments, the plasma processing apparatus 20 further includes a temperature control structure 306. The temperature control structure 306 is electrically connected to the first temperature sensing unit 304 and the second temperature sensing unit 305, and configured to control the temperature of the edge adjustment ring according to the first measurement result and the second measurement result.

It should be noted that the temperature control structure can obtain the temperature of the edge adjustment ring through the first measurement result of the first temperature sensing unit, and obtain the temperature in the processing chamber of the plasma processing apparatus through the second measurement result of the second temperature sensing unit. When the temperature of the edge adjustment ring is higher than the temperature in the processing chamber, the temperature control structure adjusts the temperature of the edge adjustment ring. Here, adjusting the temperature of the edge adjustment ring may be achieved by adjusting the temperature of the edge adjustment ring by controlling the second thermally conductive structure.

According to the plasma processing apparatus provided by the embodiments of this disclosure, the temperature of the edge adjustment ring is adjusted by the first temperature sensing unit and the second temperature sensing unit so as to form a temperature adjustment mechanism, thereby avoiding the problem that the temperature of the plasma treatment apparatus can only be changed passively, but cannot be actively adjusted. Moreover, in the embodiments of this disclosure, the temperatures obtained by the two temperature sensing units are compared, to avoid the problem of an abnormality of the plasma processing apparatus caused by a temperature alarm of one of the temperature sensors due to a non-temperature problem.

FIG. 3F is a partial schematic structural diagram of a plasma processing apparatus provided by the embodiments of this disclosure. As shown in FIG. 3F, the plasma processing apparatus 20 further includes a reminder structure 308, which is electrically connected to the first temperature sensing unit 304 and the second temperature sensing unit 305, and configured to output, in response to an absolute value of the difference between the first measurement result and the second measurement result being greater than a preset threshold, an indication signal indicating that the temperature of the plasma processing apparatus is abnormal.

Here, the preset threshold is set by a technician according to actual conditions. The preset threshold may be 20 degrees Celsius (° C.) or 30° C. The value of the preset threshold is not limited in the embodiments of this disclosure.

In some embodiments, the outputting an indication signal may be outputting a voice prompt, or a flashing signal light prompt. The outputting mode of the indication signal is not limited in this disclosure.

According to the plasma processing apparatus provided by the embodiments of this disclosure, whether the temperature of the plasma processing apparatus is abnormal is determined by the temperature values obtained by the first temperature sensing unit and the second temperature sensing unit, and if the temperature is abnormal, an indication signal will be sent to indicate that the apparatus is abnormal, thereby improving the use safety of the plasma processing apparatus.

FIG. 3G is a partial schematic structural diagram of a plasma processing apparatus provided by the embodiments of this disclosure.

In some embodiments, as shown in FIG. 3G, the plasma processing apparatus 20 further includes a transmission structure 309 and a data analysis structure 310. The transmission structure 309 is electrically connected to the temperature control structure 308 and the data analysis structure 310, and is configured to receive data generated during temperature adjustment and sent by the temperature control structure 308 and transmit the data to the data analysis structure 310. The data analysis structure 310 is configured to analyze the received data to obtain an analysis result.

In some embodiments, the data analysis structure may be provided with a display screen. The display screen is configured for displaying the data and the analysis result, so that a relevant technician can view the data and analysis result through the display screen.

According to the plasma processing apparatus provided by the embodiments of this disclosure, data generated when the temperature control structure performs temperature adjustment is analyzed and saved, so that a technician can view the temperature adjustment data again, and adjust and maintain the plasma processing apparatus, thereby improving the safety and service life of the plasma processing apparatus.

FIG. 3H is a partial schematic structural diagram of a plasma processing apparatus provided by the embodiments of this disclosure. As shown in FIG. 3H, the plasma processing apparatus 20 further includes a base 311 arranged around the electrostatic chuck 201 in the circumferential direction, in which the edge adjustment ring 202 is located between the base 311 and the edge ring 203.

In some embodiments, a pull rod 312 is provided in the base 311, in which the pull rod 312 is configured to fix the edge adjustment ring 202.

In some embodiments, the base and the pull rod may be made of conductive materials such as aluminum or copper.

In some embodiments, the electrostatic chuck 201 further has a top surface 2012 at a side of the electrostatic chuck 201 where the connection surface is provided. In a direction perpendicular to the electrostatic chuck, the top surface 2012 of the electrostatic chuck is relatively distant from the edge adjustment ring 202, and the connection surface is relatively close to the edge adjustment ring 202. A part of the edge ring 203 in contact with the connection surface is provided with a stepped surface 2031. In the direction perpendicular to the electrostatic chuck, the top surface 2012 of the electrostatic chuck is relatively distant from the edge adjustment ring 202, and the stepped surface 2031 is relatively close to the edge adjustment ring 202.

In some embodiments, a height difference between the stepped surface 2031 and the top surface 2012 in the direction perpendicular to electrostatic chuck ranges from 0.004 feet to 0.012 feet.

In some embodiments, when the plasma processing apparatus etches a workpiece, a potential difference will be generated between the workpiece edge and the edge ring under the bombardment of plasma. When the distance between the workpiece edge and the edge ring is too small, capacitor arcing may occur between the workpiece edge and the edge ring. Therefore, in the embodiments of this disclosure, by limiting the height difference between the stepped surface and the top surface, the distance between the workpiece edge and the edge ring is limited, thereby alleviating the problem of capacitor arcing caused by potential difference generated between the workpiece edge and the edge ring when performing a plasma processing task.

In the embodiments of this disclosure, the position of the edge ring is fixed by the annular protrusion of the edge adjustment ring, so that the height difference between the top surface of the electrostatic chuck and the stepped surface of the edge ring is within a reasonable range, thereby avoiding capacitor arcing between the workpiece and the edge ring during etching.

It should be understood that the device and method disclosed in several embodiments provided in this disclosure may be implemented in a non-target manner The device embodiments described above are merely exemplary. For example, the unit division is merely logical function division and may be actually implemented in other division manners. For example, a plurality of units or assemblies may be combined or integrated into another system, or some features may be ignored or not implemented. In addition, the components shown or discussed are mutually coupled or directly coupled.

The units described as separate components may or may not be physically separate, and the components shown as units may or may not be physical units, i.e., may be located at one position, or may be distributed on a plurality of network units. Some or all of the units may be selected according to actual needs to achieve the objectives of the solutions of the embodiments.

The features disclosed in the method or device embodiments provided by this disclosure can be arbitrarily combined without causing conflicts so as to obtain a new method or device embodiment.

The descriptions above are only some implementations of this disclosure. However, the scope of protection of this disclosure is not limited thereto. Within the technical scope disclosed by this disclosure, any variation or substitution that can be easily conceived of by those skilled in the art should all fall within the scope of protection of this disclosure. Therefore, the scope of protection of this disclosure should be determined by the scope of protection of the claims.

1. A plasma processing apparatus, comprising:
an electrostatic chuck, wherein a connection surface is provided at a periphery of the electrostatic chuck;
an edge adjustment ring, arranged around the electrostatic chuck in a circumferential direction, wherein an inner wall of the edge adjustment ring is opposite to an outer wall of the electrostatic chuck; and
an edge ring, arranged around the electrostatic chuck and above the connection surface, and located above the edge adjustment ring,
wherein the edge adjustment ring comprises an annular body and an annular protrusion protruding toward the edge ring, and the annular body is relatively close to the electrostatic chuck.

2. The plasma processing apparatus of claim 1, wherein the edge adjustment ring further comprises:
grooves recessed in a direction away from the edge ring, and located at a surface of the annular body relatively close to the edge ring and between the annular protrusion and the electrostatic chuck.

3. The plasma processing apparatus of claim 2, further comprising:
a first thermally conductive structure, located between the annular body and the edge ring, configured to bond the edge adjustment ring and the edge ring, and further configured to transfer heat between the annular body and the edge ring.

4. The plasma processing apparatus of claim 3, wherein
the first thermally conductive structure partially fills in the grooves, such that there are gaps between a bottom of the first thermally conductive structure and bottoms of the grooves, and volume of a gap is smaller than that of a groove.

5. The plasma processing apparatus of claim 1, further comprising:
a cooling assembly, located below the electrostatic chuck and configured to cool the electrostatic chuck; and
a second thermally conductive structure, located in the annular body and in contact with the cooling assembly, and configured to conduct heat to the cooling assembly.

6. The plasma processing apparatus of claim 5, wherein the plasma processing apparatus comprises:
a plurality of second thermally conductive structures, located in the annular body and disposed at equal intervals in a circumferential direction of the annular body.

7. The plasma processing apparatus of claim 5, further comprising:
a first temperature sensing unit, located in the edge adjustment ring, and configured to measure a temperature of the edge adjustment ring to obtain a first measurement result; and
a second temperature sensing unit, located in a cavity of the plasma processing apparatus, and configured to measure a temperature in the plasma processing apparatus to obtain a second measurement result, wherein the cavity is configured to accommodate the electrostatic chuck, the edge adjustment ring, and the edge ring.

8. The plasma processing apparatus of claim 7, further comprising:
a temperature control structure, electrically connected to the first temperature sensing unit and the second temperature sensing unit, and configured to control the temperature of the edge adjustment ring according to the first measurement result and the second measurement result.

9. The plasma processing apparatus of claim 8, further comprising:
a reminder structure, electrically connected to the first temperature sensing unit and the second temperature sensing unit, and configured to output, in response to an absolute value of a difference between the first measurement result and the second measurement result being greater than a preset threshold, an indication signal indicating that a temperature of the plasma processing apparatus is abnormal.

10. The plasma processing apparatus of claim 8, further comprising: a transmission structure and a data analysis structure, wherein
the transmission structure is electrically connected to the temperature control structure and the data analysis structure, and configured to receive data generated during temperature adjustment and sent by the temperature control structure, and transmit the data to the data analysis structure; and
the data analysis structure is configured to analyze the data received to obtain an analysis result.

11. The plasma processing apparatus of claim 1, further comprising:
a base, arranged around the electrostatic chuck in the circumferential direction, wherein the edge adjustment ring is located between the base and the edge ring.

12. The plasma processing apparatus of claim 11, wherein a pull rod is provided in the base and configured to fix the edge adjustment ring.

13. The plasma processing apparatus of claim 1, wherein
the electrostatic chuck further has a top surface on a side of the electrostatic chuck where the connection surface is provided;
in a direction perpendicular to the electrostatic chuck, the top surface of the electrostatic chuck is relatively distant from the edge adjustment ring, and the connection surface is relatively close to the edge adjustment ring;
a part of the edge ring in contact with the connection surface is provided with a stepped surface; and
in the direction perpendicular to the electrostatic chuck, the top surface of the electrostatic chuck is relatively distant from the edge adjustment ring, and the stepped surface is relatively close to the edge adjustment ring.

14. The plasma processing apparatus of claim 13, wherein
a height difference between the stepped surface and the top surface in the direction perpendicular to the electrostatic chuck ranges from 0.004 feet to 0.012 feet.

15. The plasma processing apparatus of claim 1, wherein the edge adjustment ring is made of ceramic.
